(19) United States
(12) Patent Application Publication
(10) Pub. No.: US 2008/0254645 A1
(43) Pub. Date: Oct. 16, 2008

(54) LIGHT IRRADIATION APPARATUS, CRYSTALLIZATION APPARATUS, CRYSTALLIZATION METHOD, AND DEVICE

(76) Inventor: Yukio TANIGUCHI, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 11/851,739

(22) Filed: Sep. 7, 2007

(30) Foreign Application Priority Data
Sep. 20, 2006 (JP) 2006-254236

(51) Int. Cl. H01L 21/00; B01D 9/00

(52) U.S. Cl. 438/795; 422/245.1; 257/E21.001

(57) ABSTRACT

A light irradiation apparatus includes a light modulation element which has a step line of a phase step having a phase difference different from 180 degrees, and modulates a phase of incident light. An illumination optical system illuminates the modulation element with illumination light inclined in a direction perpendicular to the step line. An image forming optical system forms a light intensity distribution on a crystallized plane, based on the light subjected to phase modulation. The illumination optical system simultaneously illuminates the modulation element with first light which illuminates the modulation element along a first direction extending from a phase advance side toward a phase retardation side of the phase step and second light which illuminates the modulation element along a second direction extending from the phase retardation side toward the phase advance side, and has a light intensity setting mechanism which sets different light intensities of the first and second lights.

### CROSS-REFERENCE TO RELATED APPLICATIONS

This application is based upon and claims the benefit of priority from prior Japanese Patent Application No. 2006-254236, filed Sep. 20, 2006, the entire contents of which are incorporated herein by reference.

### BACKGROUND OF THE INVENTION

1. Field of the Invention

The present invention relates to a light irradiation apparatus, a crystallization apparatus, a crystallization method, and a device. More particularly, the present invention relates to a technology of irradiating a non-single-crystal semiconductor film with light having a light intensity distribution to generate a crystallized semiconductor film.

2. Description of the Related Art

A thin-film transistor (TFT) for use in, e.g., a switching element which selects a display pixel in a liquid crystal display (LCD) is usually formed by using amorphous silicon or polysilicon.

The polysilicon has a higher mobility of electrons or holes than that of the amorphous silicon. Therefore, when using the polysilicon to form a transistor, a switching speed is increased and response of a display becomes thereby faster as compared with an example of using the amorphous silicon to form a transistor. Further, a peripheral LSI can be constituted of a thin-film transistor. Furthermore, the polysilicon has an advantage of, e.g., reducing a design margin of any other component. Moreover, when incorporating peripheral circuits, e.g., a driver circuit or a DAC in the display, these peripheral circuits can be operated at a higher speed.

Since the polysilicon is formed of an aggregate of crystal grains, when, e.g., a TFT transistor is formed, crystal grain boundaries inherently present in a channel region, the crystal grain boundary functions as a barrier, and a mobility of electrons or holes is lowered as compared with a channel formed in single-crystal silicon. Additionally, in many thin-film transistors formed on a substrate (single) made of polysilicon, the number of crystal grain boundaries formed in a channel portion varies depending on each thin-film transistor, and this becomes unevenness, resulting in a problem of display unevenness in case of a liquid crystal display. Thus, in recent years, in order to improve a mobility of carries and reduce unevenness in the number of crystal grain boundaries in a channel portion, a crystallization method of producing crystallized silicon with a large crystal particle diameter which is a size enabling forming at least one channel region has been proposed.

As this type of crystallization method, a “phase control ELA (Excimer Laser Annealing) method” of irradiating a phase shifter (a light modulation element) with an excimer laser beam and then irradiating a non-single-crystal semiconductor film (a polycrystal semiconductor film or a non-single-crystal semiconductor film) with a resultant Fresnel diffraction image or an image formed by an image forming optical system to produce a crystallized semiconductor film has been conventionally known. Particulars of the phase control ELA method are disclosed in, e.g., Surface Science, Vol. 21, No. 5, pp. 278-287, 2000.

In the phase control ELA method, a light intensity distribution having an inverse peak pattern (e.g., a V-shaped pattern in which a light intensity is minimum at the center and it is precipitously increased toward a periphery) where a light intensity is lower at a point corresponding to a phase shift portion in a phase shifter than that at the periphery is generated, and a non-single-crystal semiconductor film is irradiated with light having this light intensity distribution with the inverse peak shape. As a result, in an irradiation target region, a temperature gradient is produced in a fusing region in accordance with the light intensity distribution, and a crystal nucleus is formed at a part which is solidified first or a part which is not fused in accordance with a point where the light intensity is minimum. A crystal laterally grows from this crystal nucleus toward the periphery (which will be referred to as “lateral growth” or “growth in a lateral direction” hereinafter), thereby generating a single-crystal grain with a large particle diameter.

The present applicant have proposed a method of illuminating a light modulation element having a phase step with a phase difference substantially different from 180 degrees with illumination light inclined in a direction substantially perpendicular to a step line of the phase step (which will be referred to as an “oblique illumination method” hereinafter) in a light irradiation apparatus using the light modulation element (see, e.g., JP-A 2006-80490 (KOKAI) (U.S. application Ser. No. 11/198,185) and JP-A 2006-100771 (KOKAI)). In this oblique illumination method, when the light modulation element having the phase step with the phase difference which is, e.g., substantially larger than 0 degree and substantially smaller than 180 degrees is illuminated with illumination light emitted from a phase advance side toward a phase retardation side of the phase step, a light intensity distribution having an inverse peak shape produced by the phase step becomes symmetrical in a lateral direction, and a change in the light intensity distribution due to defocus is reduced.

In the phase control ELA method according to JP-A 2006-80490 (KOKAI), the lowest light intensity (which will be referred to as a “dip intensity” hereinafter) in a light intensity distribution having an inverse peak shape (which will be referred to as a “dip” hereinafter) is important. That is because polycrystal silicon (a fine crystal state) is generated in a region having a given predetermined light intensity or below, and a crystal having a large particle diameter is obtained based on lateral growth in a region having the predetermined light intensity or above. This predetermined light intensity is called a “lateral growth start intensity”. When a dip intensity is larger than the lateral growth start intensity or when the dip intensity considerably smaller than the lateral growth start intensity, the crystal breaks apart or a crystal grain becomes small.

The lateral growth start intensity is approximately several-hundred mJ/cm², and this varies depending on a material composition of an irradiation target material or a film structure. The irradiation target material is constituted of, e.g., a substrate, a lower insulating film, a semiconductor film, and an upper insulating film. In particular, the semiconductor thin film or the upper insulator film is generally formed by a method, e.g., CVD or sputtering, its composition or film thickness is generally uneven. As a result, and the lateral growth start intensity varies in accordance with a production lot of the irradiation target material.

In the conventional technology, a plurality of light modulation elements having different dip intensities are fabricated, several or many light modulation elements are prepared, and the light modulation element which realizes an optimum dip intensity with respect to each lot of the irradiation target material is selectively used. In this case, a step of manufacturing the light modulation elements having a plurality of characteristics is required. Additionally, the dip intensities cannot be continuously adjusted. In other words, many light modulation elements must be prepared to substantially continuously adjust the dip intensities.

### BRIEF SUMMARY OF THE INVENTION

It is an object of the present invention to provide a technology which can variably realize an optimum dip intensity associated with characteristics of an irradiation target material without preparing and appropriately replacing a plurality of light modulation elements having different characteristics and can stably form a crystal grain with a desired size.

To achieve this object, according to a first aspect of the present invention, there is provided a light irradiation apparatus comprising:

a light modulation element which has a phase step having a phase difference substantially different from 180 degrees;

an illumination optical system which illuminates the light modulation element with illumination light inclined in a direction substantially perpendicular to a step line of the phase step; and

an image forming optical system which forms a predetermined light intensity distribution on a predetermined plane based on the light subjected to phase modulation by the light modulation element,

wherein the illumination optical system simultaneously illuminates the light modulation element with first illumination light which illuminates the light modulation element along a first direction extending from a phase advance side toward a phase retardation side of the phase step and second illumination light which illuminates the light modulation element along a second direction extending from the phase retardation side toward the phase advance side of the phase step, and has a light intensity setting mechanism which sets a light intensity of the first illumination light and a light intensity of the second illumination light to values substantially different from each other.

According to a second aspect of the present invention, there is provided a crystallization apparatus comprising: the light irradiation apparatus according to the first aspect; and a stage which holds a non-single-crystal semiconductor film on the predetermined plane, wherein the crystallization apparatus irradiates the non-single-crystal semiconductor film held on the predetermined plane with light having the predetermined light intensity distribution to generate a crystallized semiconductor film.

According to a third aspect of the present invention, there is provided a crystallization method which uses the light irradiation apparatus according to the first aspect to irradiate a non-single-crystal semiconductor film held on the predetermined plane with light having the predetermined light intensity distribution, thereby generating a crystallized semiconductor film.

According to a fourth aspect of the present invention, there is provided a device manufactured by using the crystallization apparatus according to the second aspect or the crystallization method according to the third aspect.

In the crystallization apparatus according to a typical aspect of the present invention, changing a ratio of a light intensity of the first illumination light which illuminates the light modulation element along the first direction from the phase advance side toward the phase retardation side of the phase step and a light intensity of the second illumination light which illuminates the light modulation element along the second direction from the phase retardation side toward the phase advance side of the phase step enables variably realizing an appropriate dip intensity associated with characteristics of the irradiation target material without replacing the light modulation element. As a result, a crystal grain with a desired size can be stably formed based on the appropriate dip intensity associated with characteristics of the irradiation target material.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a view schematically showing a structure of a crystallization apparatus according to an embodiment of the present invention;

FIG. 2 is a view schematically showing an internal structure of an illumination system in the crystallization apparatus depicted in FIG. 1;

FIG. 3A is a view schematically showing a crystal state obtained when a dip intensity is slightly lower than a lateral growth start intensity, FIG. 3B is a view schematically showing a crystal state obtained when the dip intensity is larger than the lateral growth start intensity, and FIG. 3C is a view schematically showing a crystal state obtained when the dip intensity is considerably smaller than the lateral growth start intensity;

FIG. 4 is a view for explaining a definition of a phase used in the present invention;

FIG. 5 is a view showing a light modulation element in the crystallization apparatus depicted in FIG. 1 and a calculation result of a light intensity distribution obtained by obliquely illuminating this light modulation element from a forward direction;

FIG. 6 is a view showing the light modulation element and a calculation result of a light intensity distribution obtained by obliquely illuminating this light modulation element from an opposite direction;

FIG. 7 is a view showing the light modulation element, a light phase distribution immediately behind a phase step when this light modulation element is obliquely illuminated from the forward direction, and complex amplitudes in the form of vectors at points denoted by reference characters A, B and C as representative points in a point spread function range;

FIG. 8 is a view showing the light modulation element, a light phase distribution immediately behind a flat portion apart from the phase step when this light modulation element is obliquely illuminated from the forward direction, and complex amplitudes in the form of vectors at points denoted by reference characters A′, B′, and C′ as representative points in the point spread function range;

FIG. 9 is a view showing the light modulation element, a light phase distribution immediately behind the phase step when this light modulation element is obliquely illuminated from the opposite direction, and complex amplitudes in the form of vectors at points denoted by reference characters A″, B″, and C″ as representative points in the point spread function range;

FIG. 10 is a view showing a calculation result of a light intensity distribution obtained when simultaneously performing oblique illumination in the forward direction and oblique illumination in the opposite direction at a light intensity ratio of 5:1;

FIG. 11 is a view showing a calculation result of a light intensity distribution obtained when simultaneously performing oblique illumination in the forward direction and oblique illumination in the opposite direction at a light intensity ratio of 5:2;

FIG. 12 is a view for explaining a first example of changing a ratio of a light intensity in oblique illumination in the forward direction and a light intensity in oblique illumination in the opposite direction in the embodiment;

FIG. 13 is a view for explaining a second example of changing a ratio of a light intensity in oblique illumination in the forward direction and a light intensity in oblique illumination in the opposite direction in the embodiment;

FIG. 14 is a view for explaining a structure and a function of Wollaston prism used in the apparatus depicted in FIG. 13;

FIG. 15 is a view schematically showing a basic pattern of the light modulation element which can be used in the apparatus and the method according to the present invention and utilized in a numerical example;

FIG. 16 is a view showing a state where a pair of basic patterns are aligned and formed in a Y direction in the light modulation element depicted in FIG. 15;

FIG. 17 is a view showing a calculation result of a light intensity distribution obtained by obliquely illuminating the light modulation element depicted in FIG. 15 from the forward direction;

FIG. 18 is a view showing a calculation result of a light intensity distribution obtained by obliquely illuminating the light modulation element depicted in FIG. 15 from the opposite direction;

FIG. 19 is a view showing a light intensity distribution taken along a line 19-19 in FIG. 17;

FIG. 20 is a view showing a calculation result of a light intensity distribution obtained when simultaneously performing oblique illumination in the forward direction and oblique illumination in the opposite direction at a light intensity ratio of 5:1 in the numerical example;

FIG. 21 is a view showing a calculation result of a light intensity distribution obtained when simultaneously performing oblique illumination in the forward direction and oblique illumination in the opposite direction at a light intensity ratio of 5:2 in the numeral example;

FIG. 22 is a view showing a light intensity distribution taken along a line 22-22 in FIG. 20;

FIG. 23 is a view showing a light intensity distribution taken along a line 23-23 in FIG. 21; and

FIGS. 24A to 24E are process cross-sectional views showing steps of using the crystallization apparatus according to the embodiment to manufacture an electronic device.

### DETAILED DESCRIPTION OF THE INVENTION

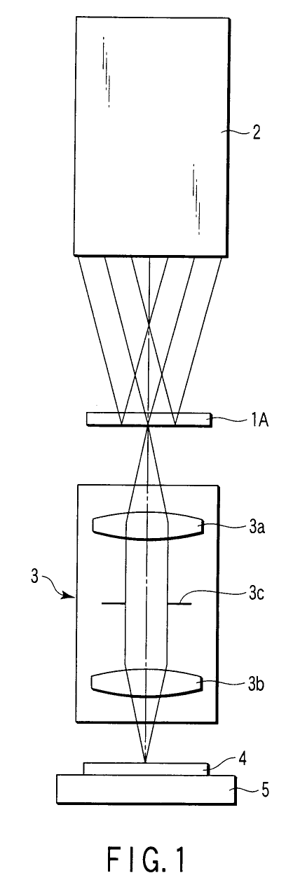

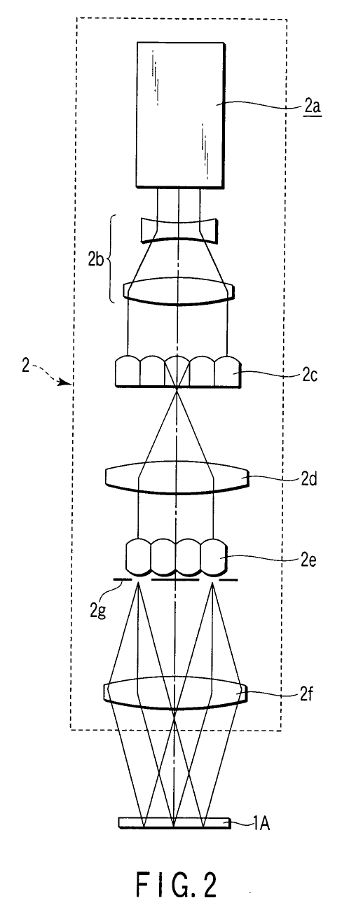

An embodiment according to the present invention will now be explained with reference to the accompanying drawings. FIG. 1 is a view schematically showing a structure of a crystallization apparatus according to the embodiment of the present invention. FIG. 2 is a view schematically showing an internal structure of an illumination system depicted in FIG. 1. Referring to FIGS. 1 and 2, the crystallization apparatus according to this embodiment includes a light modulation element 1A which modulates a phase of an incident light beam or flux to form a light beam or flux having a predetermined light intensity distribution, an illumination system 2 which illuminates the light modulation element 1A, an image forming optical system 3, and a substrate stage 5 which holds a processing target substrate 4.

A structure and a function of the light modulation element 1A will be explained later. As shown in FIG. 2, the illumination system 2 includes an XeCl excimer laser beam source 2a which supplies a laser beam having a wavelength of, e.g., 308 nm. As the beam source 2a, a continuous oscillation type or a pulse oscillation type can be used, or any other appropriate beam source having performance of emitting an energy light beam which fuses the processing target substrate 4 like a KrF excimer laser beam source or a YAG laser beam source may be used. A laser beam supplied from the beam source 2a is expanded through a beam expander 2b, and then enters a first fly-eye lens 2c.

As a result, a plurality of small beam sources are formed on a rear focal plane of the first fly-eye lens 2c, and light fluxes from the plurality of small beam sources illuminate an incidence plane of a second fly-eye lens 2e in an overlapping manner through a first condenser optical system 2d. As a result, more small beam sources than those on the rear focal plane of the first fly-eye lens 2c are formed on a rear focal plane of the second fly-eye lens 2e. Light fluxes from the plurality of small beam sources formed on the rear focal plane of the second fly-eye lens 2e illuminate the light modulation element 1A in an overlapping manner through a second condenser optical system 2f.

The first fly-eye lens 2c and the first condenser optical system 2d constitute a first homogenizer. This first homogenizer homogenizes the laser beam emitted from the beam source 2a in relation to an incidence angle on the light modulation element 1A. Further, the second fly-eye lens 2e and the second condenser optical system 2f constitute a second homogenizer. This second homogenizer homogenizes the laser beam having the incidence angle homogenized by the first homogenizer in relation to a light intensity at each in-plane position on the light modulation element 1A.

An aperture stop mechanism 2g is provided near an exit surface of the second fly-eye lens 2e, i.e., a position corresponding to exit pupils of the illumination optical systems 2b to 2f or a position near the former position. A structure and a function of the aperture stop mechanism 2g will be explained later. The laser beam having the phase modulated by the light modulation element 1A enters on the processing target substrate 4 through the image forming optical system 3. Here, in the image forming optical system 3, a phase pattern plane of the light modulation element 1A and the processing target substrate 4 are arranged in an optically conjugate relationship. In other words, the processing target substrate 4 is set to a plane (an image plane of the image forming optical system 3) which is optically conjugated with the phase pattern plane of the light modulation element 1A.

The image forming optical system 3 includes a positive lens group 3a, a positive lens group 3b, and an aperture stop 3c arranged between these lens groups. A size of an opening portion (a light transmitting portion) of the aperture stop 3c (i.e., an image-side numeral aperture NA of the image forming optical system 3) is set to generate a necessary light intensity distribution on a semiconductor film (an irradiation target plane) of the processing target substrate 4. The image forming optical system 3 may be a refractive type optical system, a reflective type optical system, or a catadioptric type optical system.

The processing target substrate 4 to be crystallized may be a non-single-crystal semiconductor film alone, a region of a non-single-crystal semiconductor film formed on the semiconductor substrate, or a non-single-crystal semiconductor film supported on a support. An example where the processing target substrate 4 is supported on a support will be explained hereinafter.

The processing target substrate 4 is constituted by forming a lower insulating film, a semiconductor thin film, and an upper insulating film on a support or a substrate in the mentioned order. In more detail, according to this embodiment, the processing target substrate 4 is obtained by sequentially forming a underlying insulating film, a non-single-crystal film, e.g., an amorphous silicon film, and a cap film on, e.g., a liquid crystal display glass sheet based on a chemical vapor deposition method (CVD). Each of the underlying insulating film and the cap film is an insulating film, e.g., an SiO₂ film. The underlying insulating film prevents foreign particles, e.g., Na in the glass substrate from being mixed in the amorphous silicon film when the amorphous silicon film directly comes into contact with the glass substrate, and also prevents heat of the amorphous silicon film from being directly transmitted to the glass substrate.

The amorphous silicon film is a semiconductor film (a non-single-crystal semiconductor film) to be crystallized. The cap film is heated by a part of the light beam which enters the amorphous silicon film, and stores a temperature when heated. When incidence of the light beam is blocked, a temperature in a high-temperature portion is relatively rapidly lowered on an irradiation target plane of the amorphous silicon film. However, this heat storage effect alleviates this temperature-down gradient, and promotes lateral crystal growth with a large particle diameter. The processing target substrate 4 is positioned and held at a predetermined position on the substrate stage 5 by, e.g., a vacuum chuck or an electrostatic chuck.

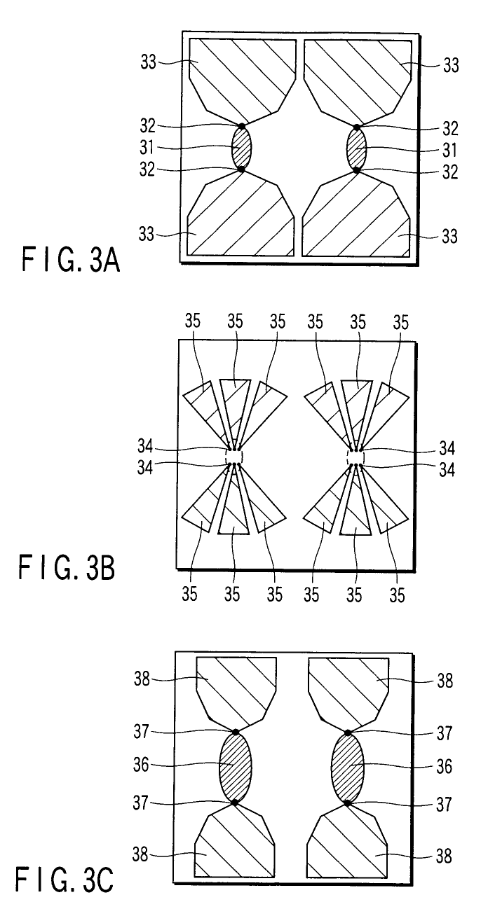

Prior to a specific explanation of this embodiment, the fact that a dip intensity is important in the phase control ELA method will be explained. FIG. 3A shows a crystal state obtained when a dip intensity is slightly lower than a lateral growth start intensity. In this case, each of polysilicon regions 31 which is an aggregate of fine crystals is generated at each dip position, and fine crystals around the polysilicon region 31 serve as growth start points 32, and lateral growth begins from each of the growth start points 32, thereby obtaining each crystal 33 with a large particle diameter or large area.

FIG. 3B shows a crystal state obtained when the dip intensity is larger than the lateral growth start intensity. In this case, since any of the polysilicon regions is not generated, a crystal laterally grows from each of many growth start points 34, thereby forming a plurality of fragmented crystal grains 35. Furthermore, since a light intensity gradient, i.e., a temperature gradient at a dip becomes moderate when the dip intensity is high, lateral growth of each crystal 35 breaks off, and a probability that a large crystal grain is not formed is increased.

FIG. 3C shows a crystal state obtained when the dip intensity is considerably smaller than the lateral growth start intensity. In this case, as compared with the example depicted in FIG. 3A, a polysilicon region 36 formed at each dip position becomes too large, and each crystal grain 38 obtained based on lateral growth from each growth start point 37 around the polysilicon region 36 becomes small. In order to form a transistor on a crystal having a desired size, as shown in FIG. 3A, setting the dip intensity to be slightly lower than the lateral growth start intensity is important as explained above.

On the other hand, as mentioned above, the lateral growth start intensity in the processing target substrate 4 varies in accordance with each production lot. Thus, the present inventor has found a technique of variably realizing an appropriate dip intensity associated with characteristics of an irradiation target material (the processing target substrate 4) without replacing the light modulation element, i.e., a technique of changing illumination conditions by utilizing features of a oblique illumination method to vary a dip intensity without replacing the light modulation element. A principle of the technique according to the present invention will now be explained.

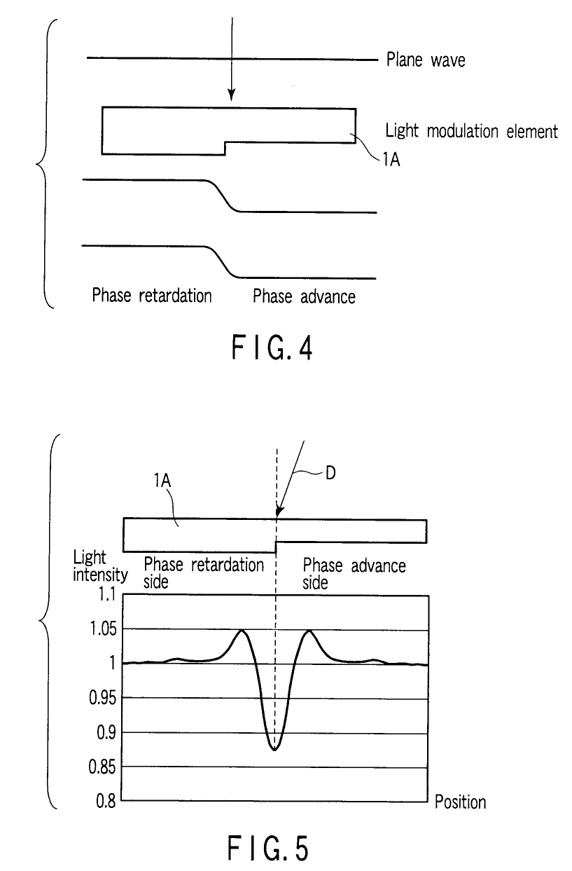

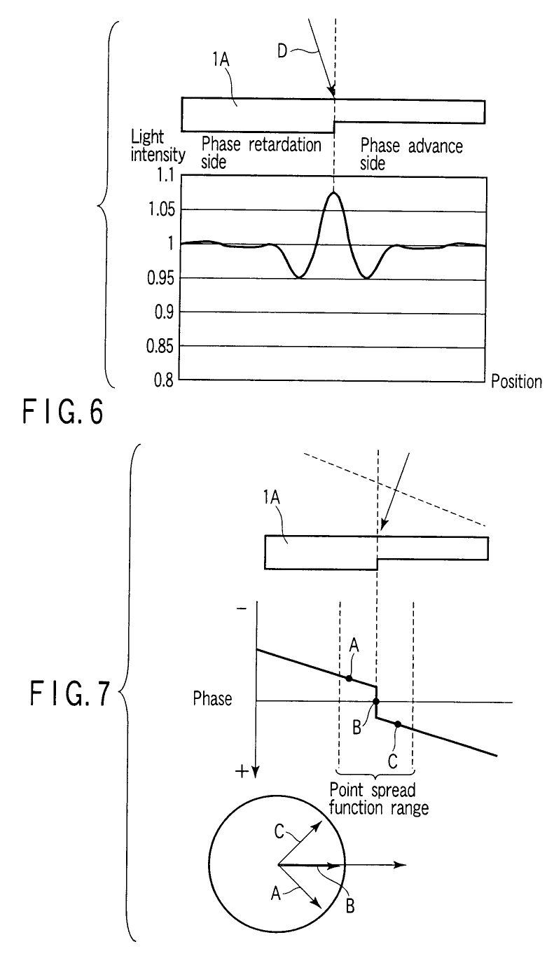

In order to simplify an explanation of the principle, a consideration will be first given on an example where the light modulation element having a phase step with a geometrical step structure is obliquely illuminated, which is specifically an example where the light modulation element 1A (see FIGS. 5 and 6) in which a phase difference (a phase angle) of a phase step is 40 degrees is obliquely illuminated. First, referring to FIG. 4, a definition of a phase used in the present invention will be explained. Considering a wave front immediately behind the light modulation element (a phase shifter) 1A to which a plane wave has entered, a region in case of shifting in a light advancing direction is determined as a region on a “phase advance” side, and a region in case of shifting toward the beam source side is determined as a region on a “phase retardation” side.

When the phase step is formed of an irregular shape on a substrate surface like the light modulation element 1A, a convex side of both sides of the step is a phase retardation side and a concave side of the same is a phase advance side. This definition can be likewise applied to a light modulation element having a shape other than the irregular shape. Further, a method of controlling a phase by using a fine pattern which is equal to or smaller than a resolution of the image forming optical system to be used can be considered, but applying the same definition to a phase distribution formed on an image plane can suffice in this case. Furthermore, when using a phase value in an explanation of the light modulation element, this value is positive in a phase advance direction. For example, a value of +90 degrees means a phase advance of 90 degrees, and a value of −90 degrees means a phase retardation of 90 degrees.

Since the light modulation element 1A has a phase step with a phase difference which is substantially larger than 0 degree and substantially smaller than 180 degrees, illumination along a direction from the phase advance side toward the phase retardation side of the phase step (indicated by an arrow D in FIG. 5) is called “oblique illumination in a forward direction”, and illumination along a direction from the phase retardation side toward the phase advance side of the phase step (see FIG. 6) is called “oblique illumination in an opposite direction”. It is to be noted that, in this specification, when the light modulation element has a phase step with a phase difference which is substantially larger than 180 degrees and substantially smaller than 360 degrees, illumination along a direction from the phase retardation side toward the phase advance side of the phase step is called “oblique illumination in a forward direction”, and illumination along a direction from the phase advance side toward the phase retardation side of the phase step is called “oblique illumination in an opposite direction”.

An example of calculation conditions for a light intensity distribution obtained by obliquely illuminating the light modulation element 1A is as follows. That is, a wavelength of light is 308 nm, an object-side numerical aperture of the image forming optical system 3 is 0.15, a coherence factor (an illumination a value; an exit-side numerical aperture of the illumination system 2/the object-side numerical aperture of the image forming optical system 3) is 0.5, an image forming magnification of the image forming optical system 3 is ⅕, and an oblique illumination angle is ±0.7 degree (a positive value is an angle of oblique illumination in the forward direction, and a negative value is an angle of oblique direction in the opposite angle).

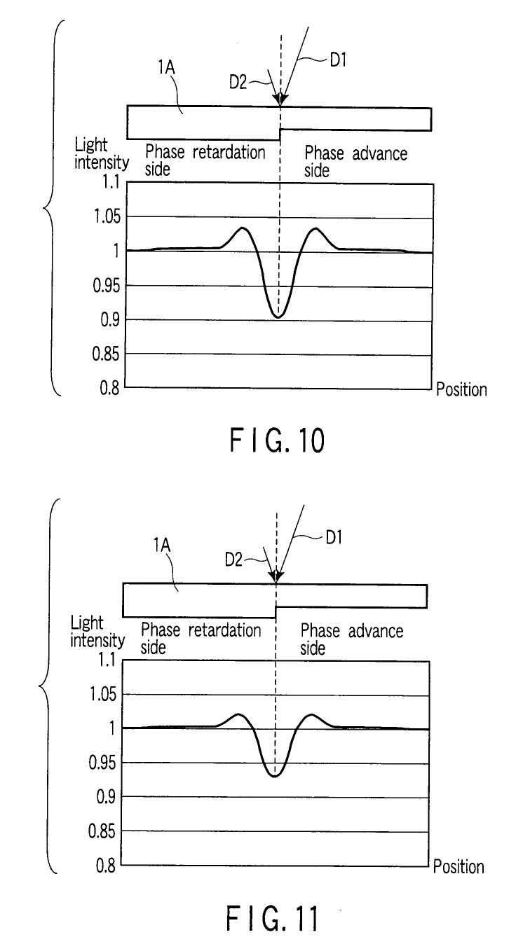

FIG. 5 is a view showing a calculation result of a light intensity distribution obtained by obliquely illuminating the light modulation element 1A from the forward direction. FIG. 6 is a view showing a calculation result of a light intensity distribution obtained by obliquely illuminating the light modulation element 1A in the opposite direction. In each of FIGS. 5 and 6, an ordinate represents a light intensity when an intensity at the time of no modulation is standardized as 1, and an abscissa represents a position on the processing target substrate 4. This representation can be likewise applied to FIGS. 10, 11, 19, 22, and 23.

Referring to FIG. 5, when the light modulation element 1A is obliquely illuminated from the forward direction, a light intensity distribution having an inverse peak shape (an intensity having a minimum peak value), i.e., a dip is formed on the processing target substrate 4 at a position corresponding to the phase step. As disclosed in JP-A 2006-80490 (KOKAI), the light intensity distribution having an inverse peak shape generated based on oblique illumination in the forward direction is symmetrical in a lateral direction (the phase retardation direction and the phase advance direction), and a change in the light intensity distribution due to defocus is small. On the other hand, as shown in FIG. 6, when the light modulation element 1A is obliquely illuminated in the opposite direction, a light intensity distribution having a peak shape (an intensity having a maximum peak value) is generated on the processing target substrate 4 at a position corresponding to the phase step. In oblique illumination in the opposite direction, like oblique illumination in the forward direction, the light intensity distribution having the peak shape is symmetrical in the lateral direction, and a change in the light intensity distribution due to defocus is small.

A reason for generation of the light intensity distribution having the inverse peak shape in oblique illumination in the forward direction and generation of the light intensity distribution having the peak shape in oblique illumination in the opposite direction will now be explained with reference to FIGS. 7 to 9. FIG. 7 is a view showing a light phase distribution immediately behind the phase step when the light modulation element 1A is obliquely illuminated in the forward direction and also showing complex amplitudes in the form of vectors at points denoted by reference characters A, B, and C as representative points in a point spread function range. Referring to FIG. 7, it can be understood that a fixed gradient is added as well as the phase step in the light phase distribution immediately behind the phase step based on oblique illumination in the forward direction. The point spread function range will now be explained hereinafter.

Paying attention to a point P′ (not shown) on the processing target substrate 4 corresponding to a point P (not shown) on the light modulation element 1A, a light complex amplitude distribution U (P′) at the point P′ is obtained based on a convolution of a point spread function distribution PSF (x, y) determined by the image forming optical system 3 and an amplitude transmission factor distribution T (x, y) of the light modulation element 1A as represented by the following Expression (1) (approximation in a coherent imagery theory). Here, (x, y) means a coordinate on the light modulation element 1.

U(P′)=PSF(x,y)*T(x,y) (1)

The point spread function distribution PSF (x, y) is cut off at a point 0 which is closest to an origin (the center of the distribution), approximation is performed on the assumption that a value is fixed in this range, and this range is called a “point spread function range”. That is, the point spread function range of the image forming optical system 3 is a range surrounded by a line which becomes 0 or can be regarded as 0 in the point spread function. In general, the point spread function range is represented as a circle having a radius of 0.61λ/NA on the image plane where NA is an object-side numeral aperture of the image forming optical system 3 and λ is a wavelength of light, and it becomes a circle which is in proportion to a value divided by a magnification of the image forming optical system 3 on the light modulation element 1.

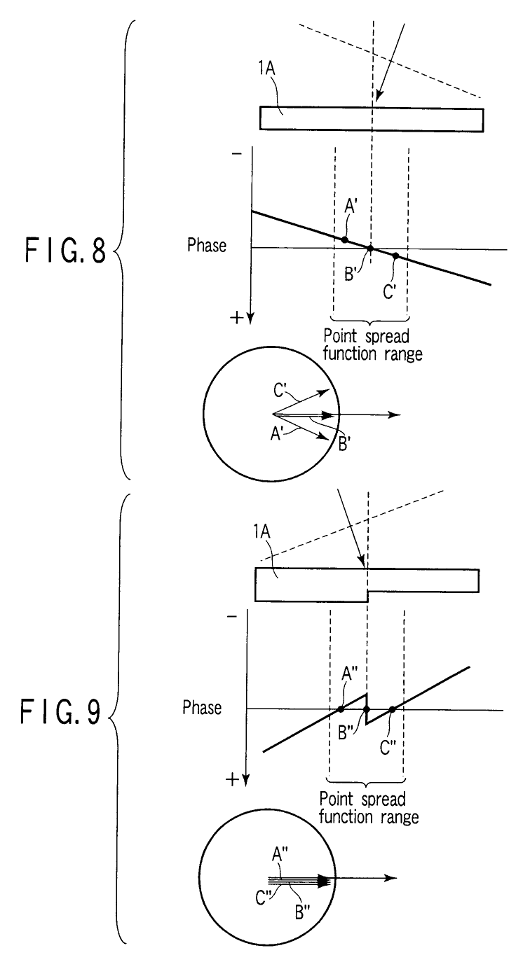

FIG. 8 is a view showing a light phase distribution immediately behind a flat portion apart from the phase step when the light modulation element 1A is obliquely illuminated in the forward direction, and also showing complex amplitudes in the form of vectors at points denoted by reference characters A′, B′, and C′ as representative points in the point spread function range. Comparing FIG. 7 with FIG. 8, in oblique illumination in the forward direction, the phase step has a larger phase difference between the representative points than the flat portion. Therefore, when the light modulation element 1A is obliquely illuminated in the forward direction, the light intensity becomes lower at a position on the processing target substrate 4 corresponding to the phase step than that at a position on the same corresponding to the flat portion, and such a light intensity distribution having an inverse peak shape, i.e., a dip as shown in FIG. 5 is generated.

FIG. 9 is a view showing a light phase distribution immediately behind the phase step when the light modulation element 1A is obliquely illuminated in the opposite direction and also showing complex amplitudes in the form of vectors at points denoted by reference characters A″, B″, and C″ as representative points in the point spread function range. Referring to FIG. 9, it can be understood that a fixed gradient which offsets the phase step is added in the light phase distribution immediately behind the phase step based on oblique illumination in the opposite direction. Although a drawing of a light phase distribution immediately behind the flat portion apart from the phase step when the light modulation element 1A is obliquely illuminated in the opposite direction is omitted, it is a phase distribution obtained by mirror-reversing the phase distribution depicted in FIG. 8. Therefore, when the light modulation element 1A is obliquely illuminated in the opposite direction, the light intensity becomes lower at a position on the processing target substrate 4 corresponding to the flat portion than that at a position on the same corresponding to the phase step, and such a light intensity distribution having a peak shape as shown in FIG. 6 is generated.

A description will now be given as to a technique according to the present invention of simultaneously performing oblique illumination in the forward direction and oblique illumination in the opposite direction and changing a ratio or a difference of a light intensity obtained based on oblique illumination in the forward direction and a light intensity obtained based on oblique illumination in the opposite direction is changed to adjust a dip intensity. FIG. 10 is a view showing a calculation result of a light intensity distribution obtained when oblique illumination in the forward direction (indicated by an arrow D1) and oblique illumination in the opposite direction (indicated by an arrow D2) are simultaneously carried out at a light intensity ratio of 5:1. In this case, it is preferable for incidence angles in both types of illumination to be substantially equal to each other as shown in the drawing, but they may be different from each other. FIG. 11 is a view showing a calculation result of a light intensity distribution obtained when oblique illumination in the forward direction and oblique illumination in the opposite direction are simultaneously carried out at a light intensity ratio of 5:2.

When obtaining the calculation results depicted in FIGS. 10 and 11, it is assumed that oblique illumination in the forward direction and oblique illumination in the opposite direction do not interfere with each other, and addition is performed in accordance with a light intensity ratio to effect standardization, thereby obtaining the light intensity distribution. Comparing FIGS. 5, 10, and 11, when a ratio of the light intensity based on oblique illumination in the forward direction and oblique illumination in the opposite direction is changed from 5:0 to 5:1 and then to 5:2, it can be understood that the dip intensity is increased from approximately 0.87 to approximately 0.91 and then to approximately 0.93 while maintaining a dip width (a width of the dip at a position where the light intensity has a maximum value) and a dip half maximum full-width (a width of the dip at a position where the light intensity has a value which is ½ of the maximum value) substantially constant.

When a ratio of the light intensity of illumination light which illuminates the light modulation element 1A along a direction extending from the phase advance side toward the phase retardation side of the phase step (oblique illumination in the forward direction in the above explanation) and the light intensity of illumination light which illuminates the light modulation element 1A along a direction extending from the phase retardation side toward the phase advance side of the phase step (oblique illumination in the opposite direction in the above explanation) is changed in this manner, an appropriate dip intensity associated with characteristics of the processing target substrate 4 can be variably realized. As a result, each crystal grain having a desired size can be stably formed based on the appropriate dip intensity associated with the characteristics of the processing target substrate 4.

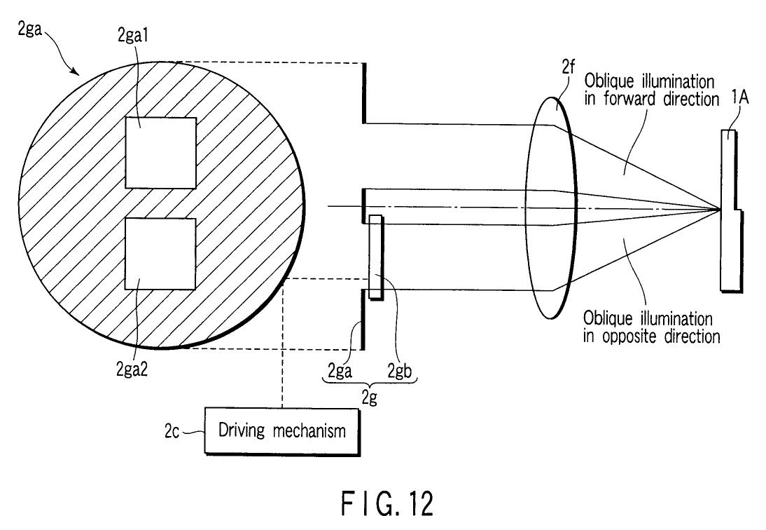

FIG. 12 is a view for explaining a first example of changing a ratio of the light intensity based on oblique illumination in the forward direction and the light intensity based on oblique illumination in the opposite direction in this embodiment. In the first example depicted in FIG. 12, an aperture stop 2ga is arranged at a position corresponding to exit pupils of the illumination optical systems 2b to 2f (FIG. 12 shows the second condenser optical system 2f alone) or a position near the former position. In the aperture stop 2ga are formed a pair of opening portions, i.e., a first opening portion 2ga1 and a second opening portion 2ga2 which are symmetrically with a straight line running through an intersection with respect to an optical axis and extending in a direction corresponding to a step line of the phase step of the light modulation element 1A at the center and each of which has a predetermined shape, e.g., a rectangular shape. Further, a transmission factor modulation filter 2gb is arranged immediately behind the second opening portion 2ga2. The aperture stop 2ga and the transmission factor modulation filter 2gb constitute the aperture stop mechanism 2g depicted in FIG. 2. As the transmission factor modulation filter 2gb, it is possible to use, e.g., a reflecting type filter which reflects extra light or an absorbing type filter which absorbs extra light.

Light transmitted through the first opening portion 2ga1 in the aperture stop 2ga obliquely illuminates the light modulation element 1A in the forward direction through the second condenser optical system 2f. On the other hand, light transmitted through the second opening portion 2ga2 in the aperture stop 2ga is subjected to a light intensity reduction by a function of the transmission factor modulation filter 2gb, and then obliquely illuminates the light modulation element 1A in the opposite direction through the second condenser optical system 2f. When the transmission factor modulation filter 2gb is replaced or adjusted in the first example depicted in FIG. 12 in this manner, the light intensity alone of the illumination light which illuminates the light modulation element 1A in the opposite direction can be reduced to a desired value, and a ratio of the light intensity of the illumination light which illuminates the light modulation element 1A in the forward direction and the light intensity of the illumination light which illuminates the same in the opposite direction can be readily adjusted (changed).

When replacing the transmission factor modulation filter 2gb, the plurality of modulation filters 2gb having different transmission factors are prepared in advance, and the filter is replaced with an appropriate one at a proper timing. In this case, an advantage that using the filter can facilitate manufacture and reduce a cost as compared with the example of replacing the light modulating element.

When adjusting the transmission factor modulation filter 2gb, a plurality of regions having different transmission degrees are formed in one filter in advance, and a region to be used can be associated with incident light by moving, e.g., the filter at a proper timing. Moreover, a region whose transmission degree continuously varies may be formed in one filter in advance, and a part of this region may be appropriately selected and used. In this example, the filter having an annular filter region whose transmission degree continuously varies is swiveled by a driving mechanism 2c to use a necessary region or part.

Although the transmission factor modulation filter 2gb is arranged immediately behind the second opening portion 2ga2 in the first example, the transmission factor modulation filter 2gb may be arranged immediately before the second opening portion 2ga2 if possible. Additionally, although the rectangular opening portions 2ga1 and 2ga2 are formed in the aperture stop 2ga in the first example, the present invention is not restricted to this structure, and shapes, arrangements, and others of the opening portions 2ga1 and 2ga2 may be modified in many ways.

Further, although the shape and the size of each of the pair of opening portions 2ga1 and 2ga2 are fixed in the first example, the present invention is not restricted thereto, and variably constituting the size of at least one of the first opening portion 2ga1 and the second opening portion 2ga2 by using a known technology enables adjusting a ratio of the light intensity of illumination light for oblique illumination in the forward direction and the light intensity of illumination light for oblique illumination in the opposite direction. In this case, the arrangement of the transmission factor modulation filter 2gb may be omitted.

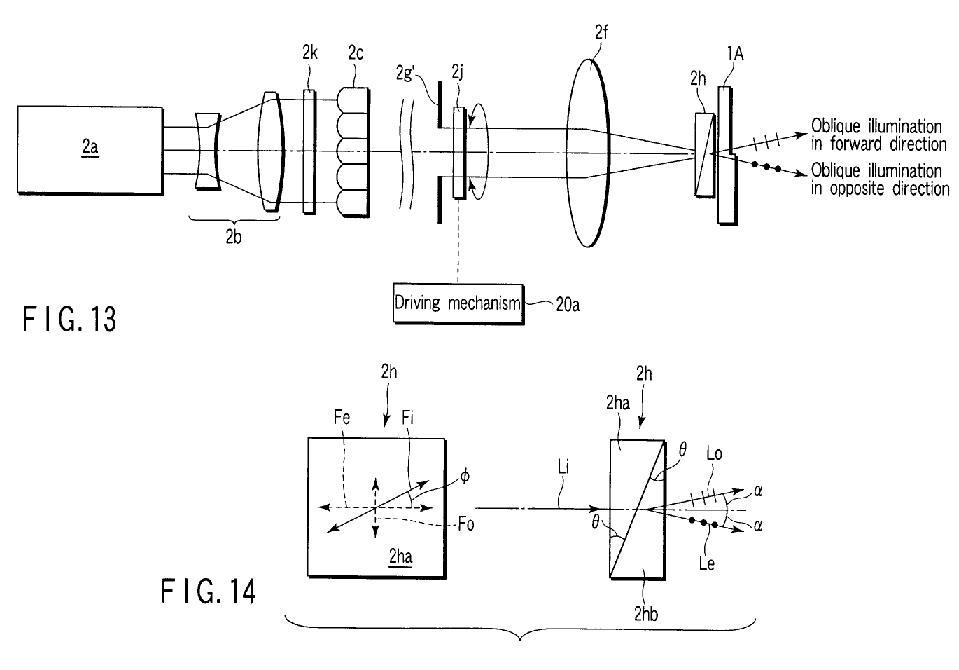

FIG. 13 is a view for explaining a second example of changing a ratio of the light intensity based on oblique illumination in the forward direction and the light intensity based on oblique illumination in the opposite direction in this embodiment. In the second example depicted in FIG. 13, a Wollaston prism 2h is arranged immediately before the light modulation element 1A, a ½λ retardation plate 2j which can be rotated by a driving mechanism 20a is arranged with an optical axis at the center on a rear side of an aperture stop 2g′ (a regular aperture stop arranged at the same position as the aperture stop 2ga depicted in FIG. 12), and a linear polarizer 2k is arranged between the beam expander 2b and the first fly-eye lens 2c. The Wollaston prism 2h is a polarizing prism from which light exits in a direction which varies depending on a polarizing direction of incident light. A structure and a function of the Wollaston prism 2h will now be explained with reference to FIG. 14.

Referring to FIG. 14, the Wollaston prism 2h is constituted by bonding a pair of right-angle prisms 2ha and 2hb each having an apex angle of θ into a parallel-plate shape. A light beam Li which has vertically entered the Wollaston prism 2h along the optical axis is separated into a normal light beam Lo which exits along a first direction forming an angle α with respect to the optical axis and an abnormal light beam Le which exits along a second direction forming an angle α with respect to the optical axis and forming an angle 2α with respect to the first direction. The separation angle α of the Wollaston prism 2h is approximated by using the following Expression (2). In Expression (2), θ is an apex angle of the right-angle prism, ne is a refraction factor of the abnormal light beam, and no is a refraction factor of the normal light beam.

$$sin α = 2 ( {n}_{e} - {n}_{o} ) tan θ \{ 1 - \frac{{( {n}_{e} - {n}_{o} )}^{2}}{2} {tan}^{2} θ \} \qquad ( 2 )$$

When linear polarized light which is polarized in a direction indicated by an arrow Fe enters the Wollaston prism 2h, the abnormal light beam Le alone is generated without producing the normal light beam Lo. On the other hand, when linear polarized light which is polarized in a direction perpendicular to the direction indicated by the arrow Fe, i.e., a direction indicated by an arrow Fo enters the Wollaston prism 2h, the normal light beam Lo alone is generated without producing the abnormal light beam Le. In general, when linear polarized light which is polarized in a direction forming an angle φ with respect to the direction indicated by the arrow Fe (a direction denoted by reference character Fi) enters the Wollaston prism 2h, a light intensity of the abnormal light beam Le:a light intensity of the normal light beam Lo is cos²φ:sin²φ.

In the second example depicted in FIG. 13, light emitted from the beam source 2a is expanded through the beam expander 2b, and then converted into linear polarized light by the linear polarizer 2k. The linear polarized light from the linear polarizer 2k enters the aperture stop 2g′ through the first fly-eye lens 2c, the first condenser optical system 2d (not shown), and the second fly-eye lens 2e (not shown). The linear polarized light transmitted through the aperture stop 2g′ is converted into linear polarized light polarized in a necessary direction by the ½λ retardation plate 2j which can rotate around the optical axis, and enters the Wollaston prism 2h via the second condenser optical system 2f (not shown).

In this manner, the abnormal light beam Le exiting from the Wollaston prism 2h obliquely illuminates the light modulation element 1A in the forward direction, and the normal light beam Lo exiting from the Wollaston prism 2h obliquely illuminates the light modulation element 1A in the opposite direction. At this time, a light polarizing direction in oblique illumination in the forward direction is perpendicular to a light polarizing direction in oblique illumination in the opposite direction, and hence it can be considered that these two types of illumination are light sources which are independent without interfering with each other. In the second example depicted in FIG. 13, changing a polarizing direction of light which enters the Wollaston prism 2h through the ½λ retardation plate 2j enables readily adjusting (varying) a ratio tan²φ of a light intensity of illumination light which obliquely illuminates the light modulation element 1A in the opposite direction with respect to a light intensity of illumination light which obliquely illuminates the same in the forward direction.

### NUMERICAL EXAMPLE

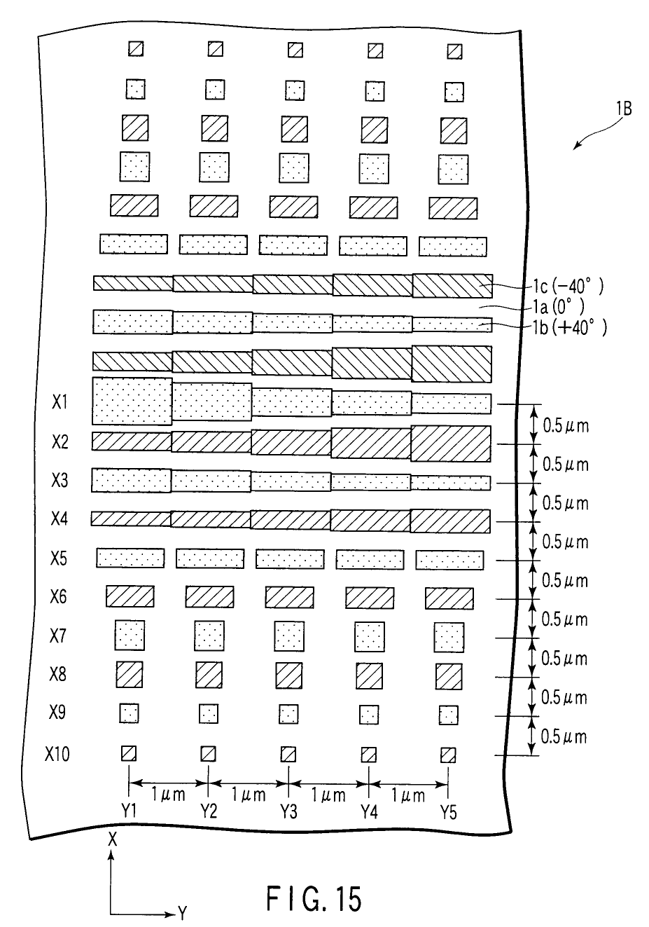

An effect of this embodiment will now be verified based on a numeral example. In the numeral example, a light modulation element 1B having a basic pattern depicted in FIG. 15 is used. In the basic pattern of the light modulation element 1B, a distance between centers of a rectangular region 1b having a phase value of +40 degrees and a rectangular region 1c having a phase value of −40 degrees along an X direction is 0.5 μm, the region 1b and the region 1c being vertically arranged to interpose a rectangular region 1a having a phase value of 0 degree. The five regions 1b of +40 degrees aligned in a row X1, the five regions 1c of −40 degrees aligned in a row X2, the five regions 1b of +40 degrees aligned in a row X3, and the five regions 1c of −40 degrees aligned in a row X4 have a dimension in a Y direction of 1 μm. It is to be noted that the dimension described herein is a value converted into an image plane considering a magnification of the image forming optical system.

Each distance between centers of the five regions 1b of +40 degrees aligned in a row X5 at intervals, the five regions 1c of −40 degrees aligned in a row X6 at intervals, the five regions 1b of +40 degrees aligned in a row X7 at intervals, the five regions 1c of −40 degrees aligned in a row X8 at intervals, the five regions 1b of +40 degrees aligned in a row X9 at intervals, and the five regions 1c of −40 degrees aligned in a row X10 at intervals is 1 μm along an X direction.

Specifically, dimensions X₊ in the X direction of the five regions 1b of +40 degrees aligned in the row X1 are 0.6 μm, 0.458 μm, 0.35 μm, 0.276 μm, and 0.24 μm in the mentioned order from the left-hand side in the drawing. The dimensions X₊ in the X direction of the five regions 1c of −40 degrees aligned in the row X2 are 0.228 μm, 0.261 μm, 0.312 μm, 0.385 μm, and 0.475 μm in the mentioned order from the left-hand side in the drawing. The dimensions X₊ in the X direction of the five regions 1b of +40 degrees aligned in the row X3 are 0.35 μm, 0.312 μm, 0.274 μm, 0.245 μm, and 0.216 μm in the mentioned order from the left-hand side in the drawing.

The dimensions X₊ in the X direction of the five regions 1c of −40 degrees aligned in the row X4 are 0.209 μm, 0.224 μm, 0.238 μm, 0.257 μm, and 0.276 μm in the mentioned order from the left-hand side in the drawing. The dimensions X₊ in the X direction of the five regions 1b of +40 degrees aligned in the row X5 at intervals are all 0.253 μm, and the dimensions Y₊ in the Y direction of the same are all 0.8 μm. The dimensions X₊ in the X direction of the five regions 1c of −40 degrees aligned in the row X6 at intervals are all 0.28 μm, and the dimensions Y₊ in the Y direction of the same are all 0.6 μm.

Both the dimension X₊ in the X direction and the dimension Y₊ in the Y direction of each of the five regions 1b of +40 degrees aligned in the row X7 at intervals are 0.366 μm. Both the dimension X₊ in the X direction and the dimension Y₊ in the Y direction of each of the five regions 1c of −40 degrees aligned in the row X8 at intervals are 0.316 μm. Both the dimension X₊ in the X direction and the dimension Y₊ in the Y direction of each of the five regions 1b of +40 degrees aligned in the row X9 at intervals are 0.257 μm. Both the dimension X₊ in the X direction and the dimension Y₊ in the Y direction of each of the five regions 1c of −40 degrees aligned in the row X10 at intervals are 0.182 μm.

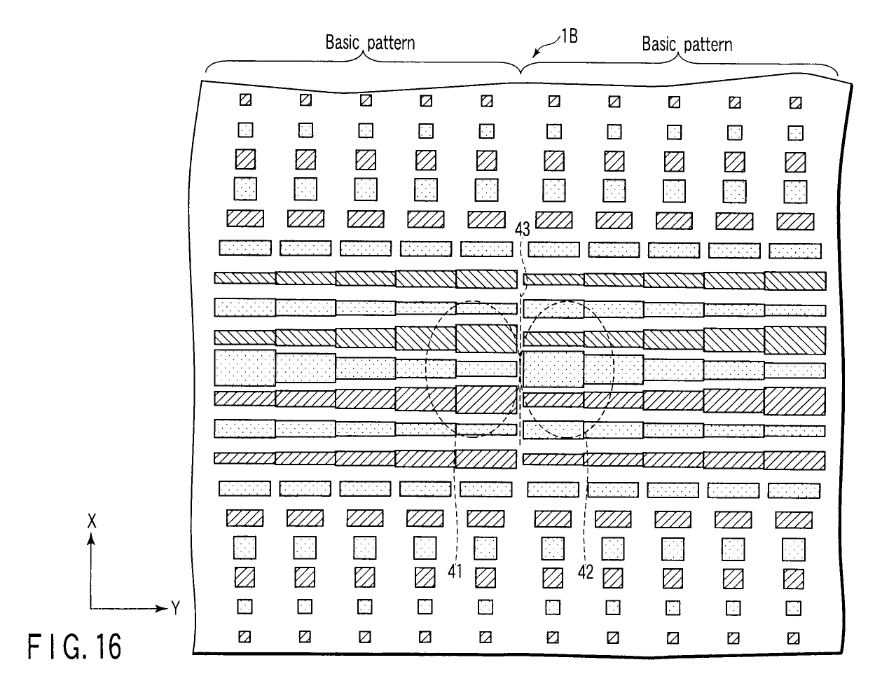

Attention is paid to the phase modulation regions on the lower side in the drawing below the five regions 1b of +40 degrees aligned in the row X1 in the above explanation. In the basic pattern of the light modulation element 1B, the phase modulation region has a symmetrical structure with respect to a central line cutting across in the Y direction the center of the five regions 1b of +40 degrees aligned in the row X1. In the light modulation element 1B, many basic patterns such as shown in FIG. 15 are two-dimensionally and repeatedly formed along the X direction and the Y direction or one-dimensionally and repeatedly formed along the Y direction. FIG. 16 shows a pair of back patterns alone which are one-dimensionally and repeatedly formed along the Y direction in many basic patterns constituting the light modulation element 1B because of space limitations.

In FIG. 16, a region indicated by an ellipse 41 of a broken line is a phase retardation region, a region indicated by an ellipse 42 of a broken line is a phase advance region, and a straight broken line 43 extending in the X direction between the phase advance region 41 and the phase retardation region 42 is a step line of the phase step. When using the light modulation element 1B, a light intensity distribution having an inverse peak shape, i.e., a dip is formed on the processing target substrate 4 at a position corresponding to the phase step, and a light intensity gradient for crystal growth is generated from the dip along the X direction. It is to be noted that reference can be made to JP-A 2006-100771 (KOKAI) in regard to a further detailed structure of the light modulation element 1B.

The phase step of the light modulation element 1A is formed of the geometrical step structure in this manner, whereas the phase step of the light modulation element 1B is formed of a difference in vectorial average value between phase modulation amounts in the point spread function range of the image forming optical system 3. The vectorial average value, i.e., an average phase value Pav of phase modulation amounts in the point spread function range of the image forming optical system 3 is defined by the following Expression (3). It is to be noted that, in Expression (3), arg is a function to obtain a phase value, x, y is a coordinate on the light modulation element, θ (x, y) is a phase at a point (x, y) on the light modulation element, and integration is carried out within the point spread function range.

Pav=arg(∫e^{-iθ(x,y)}dxdy) (3)

In the numerical example, a ratio of the light intensity of illumination light which obliquely illuminates the light modulation element 1B in the opposite direction with respect to the light intensity of illumination light which obliquely illuminates the same in the forward direction is adjusted in accordance with the second example depicted in FIG. 13. Further, in the numeral example, a wavelength of light is 308 nm, an object-side numeral aperture of the image forming optical system 3 is 0.15, and a coherence factor (an illumination σ value; an exit-side numeral aperture of the illumination system 2/the object-side numeral aperture of the image forming optical system 3) is 0.5, and an image forming magnification of the image forming optical system 3 is ⅕, an angle of oblique illumination in the forward direction is +0.71 degree, and an angle of oblique illumination in the opposite direction is −0.71 degree.

It is to be noted that, when the Wollaston prism 2h is formed of crystal, it can be understood that assigning a refraction factor of crystal ne=1.612 and no=1.602 to Expression (2) and using a right-angle prism having an apex angle θ=32° to form the Wollaston prism 2h can suffice in order to realize an oblique illumination angle α=0.71 degree. Furthermore, in the light modulation element 1B, a phase value of the phase retardation region 41 obtained by Expression (3) is −10 degrees, and a phase value of the phase advance region 42 obtained by the same is +10 degrees.

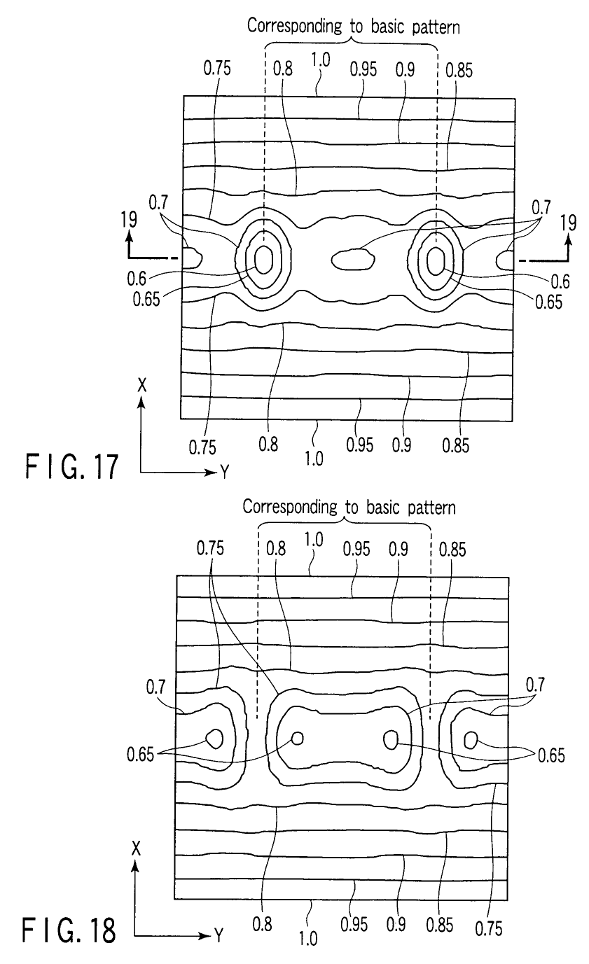

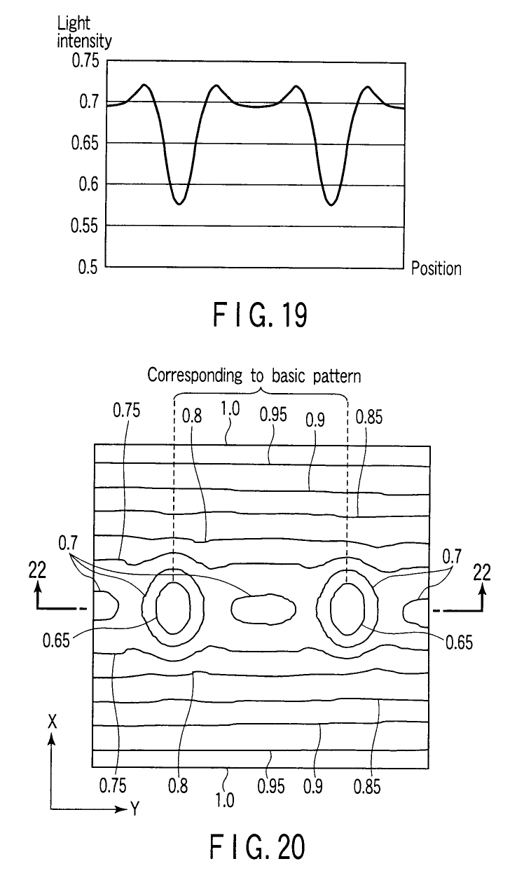

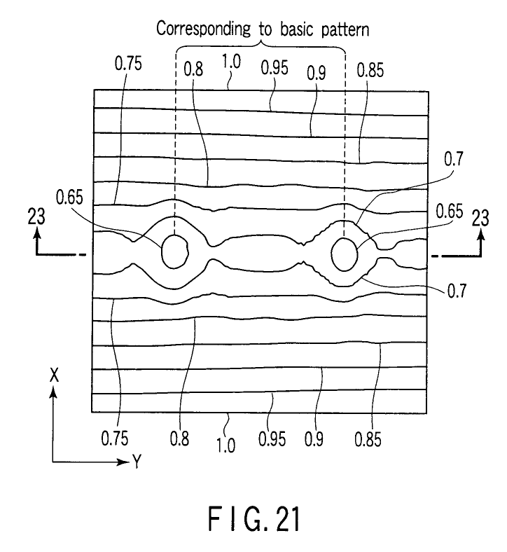

FIG. 17 is a view showing a result of calculating a light intensity distribution obtained by obliquely illuminating the light modulation element 1B in the forward direction in the numeral example. FIG. 18 is a view showing a result of calculating a light intensity distribution obtained by obliquely illuminating the light modulation element 1B in the opposite direction in the numeral example. Each of FIGS. 17 and 18 shows the light intensity distribution by using contour lines of a light intensity when an intensity at the time of no modulation is standardized as 1. This representation is also applied to FIGS. 20 and 21. Further, FIG. 19 is a view showing a light intensity distribution taken along a line 19-19 in FIG. 17. In the numeral example, oblique illumination in the forward direction is realized by setting an angle φ of light which enters the Wollaston prism 2h in a polarizing direction to 0 degree, and oblique illumination in the opposite direction is realized by setting the angle φ to 90 degrees.

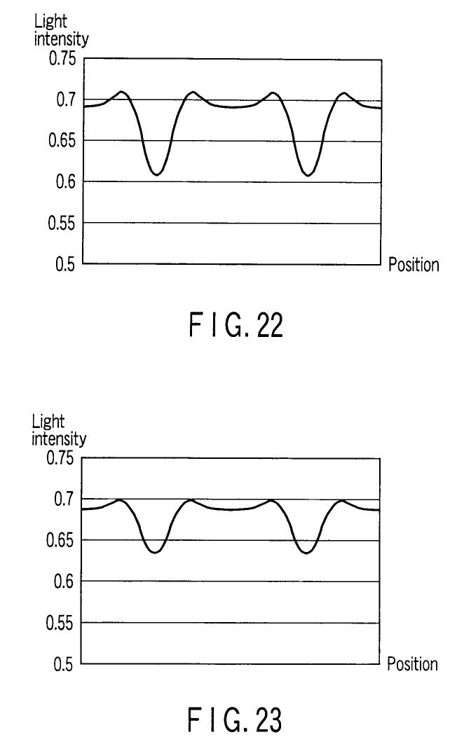

FIG. 20 is a view showing a result of calculating a light intensity distribution obtained when simultaneously performing oblique illumination in the forward direction and oblique illumination in the opposite direction at a light intensity ratio of 5:1 in the numerical example. FIG. 21 is a view showing a result of calculating a light intensity distribution obtained when simultaneously performing oblique illumination in the forward direction and oblique illumination in the opposite direction at a light intensity ratio of 5:2 in the numeral example. Furthermore, FIG. 22 is a view showing a light intensity distribution taken along a line 22-22 in FIG. 20, and FIG. 23 is a view showing a light intensity distribution taken along a line 23-23 in FIG. 21.

In the numeral example, oblique illumination in the forward direction and oblique illumination in the opposite direction are set to a light intensity ratio of 5:1 (cos²φ=0.833:sin²φ=0.167) by setting the angle φ of light which enters the Wollaston prism 2h in the polarizing direction to 24.1 degrees. Moreover, oblique illumination in the forward direction and oblique illumination in the opposite direction are set to a light intensity ratio of 5:2 (cos²φ=0.715:sin²φ=0.285) by setting the angle φ of light which enters the Wollaston prism 2h in the polarizing direction to 32.3 degrees.

Referring to FIGS. 17, 19, and 20 to 23, it was confirmed that, even if a ratio of the light intensity of oblique illumination in the forward direction and the light intensity of oblique illumination in the opposite direction is changed from 5:0 to 5:1 and then to 5:2 in the numerical example, a laterally symmetrical dip (a light intensity distribution having an inverse peak shape) is formed along the Y direction at intervals while maintaining a dip width (a width of the dip at a position where the light intensity has a maximum value) and a half maximum full-width of the dip (a width of the dip at a position where the light intensity has a value which is ½ of the maximum value) substantially constant. Additionally, it was confirmed that a light intensity gradient for crystal growth from the dip in the X direction rarely varies even if the light intensity ratio is changed in the numerical example.

In particular, comparing FIGS. 19, 22, and 23, it can be understood that a dip intensity is increased from approximately 0.58 to approximately 0.61 and then to approximately 0.63 while maintaining the dip with and the half maximum full-width of the dip substantially constant when the ratio of the light intensity of oblique illumination in the forward direction and the light intensity of oblique illumination in the opposite direction is changed from 5:0 to 5:1 and then to 5:2 in the numerical example. Incidentally, although not shown, it was confirmed that the light intensity distribution hardly varies even if the processing target substrate 4 is defocused approximately ±5 μm from a focus position of the image forming optical system 3.

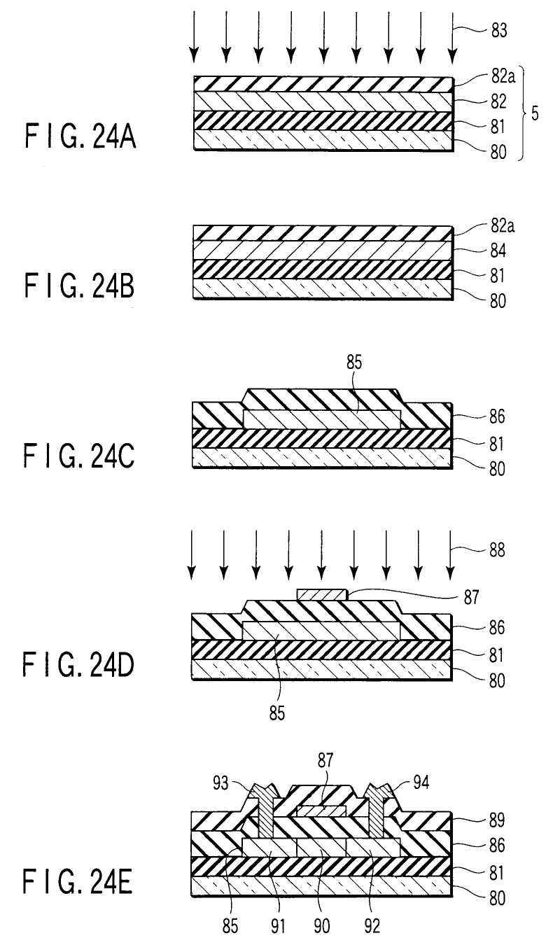

FIGS. 24A to 24E are process cross-sectional views showing respective steps of manufacturing an electronic device in a region crystallized by using the crystallization apparatus according to this embodiment. As shown in FIG. 24A, a processing target substrate 5 is prepared. The processing target substrate 5 is obtained by sequentially forming an underlying film 81 (e.g., a film like a laminated film containing SiN having a film thickness of 50 nm and SiO₂ having a film thickness of 100 nm), an amorphous semiconductor film 82 (a semiconductor film containing, e.g., Si, Ge, or SiGe having a film thickness of 50 nm to 20 nm), and a cap film 82a (e.g., an SiO₂ film having a film thickness of 30 nm to 300 nm) on a transparent insulating substrate 80 (formed of, e.g., alkali glass, quartz glass, plastic, or polyimide) by a chemical vapor deposition method or a sputtering method. Then, a predetermined region on a surface of the amorphous semiconductor film 82 is temporarily irradiated with a laser beam 83 (e.g., a KrF excimer laser beam or an XeCl excimer laser beam) once or more by using the crystallization method and apparatus adopting the light modulation element depicted in FIG. 4 or 9 according to this embodiment, thereby growing the above-explained needle-like crystals.

In this manner, as shown in FIG. 24B, a polycrystal semiconductor film or a single-crystallized semiconductor film (a crystallized region) 84 having crystal particles with a large particle diameter is formed in the irradiation region of the amorphous semiconductor film 82. Subsequently, the cap film 82a is removed from the semiconductor film 84 by etching. Thereafter, as shown in FIG. 24C, the polycrystal semiconductor film or the single-crystallized semiconductor film 84 is processed into, e.g., a plurality of an island-shaped semiconductor films (a crystallized island-shaped regions) 85 each serving as a region in which a thin film transistor is formed by using a photolithography technology as shown in FIG. 24C. An SiO₂ film having a film thickness of 20 nm to 100 nm is formed as a gate insulating film 86 on a surface of the semiconductor film 85 by using the chemical vapor deposition method or the sputtering method. Moreover, as shown in FIG. 24D, a gate electrode 87 (made of a metal e.g., silicide or MoW) is formed on a part of the gate insulating film, and the gate electrode 87 is used as a mask to implant an impurity ions 88 (phosphor in case of an N-channel transistor, or boron in case of a P-channel transistor) into the semiconductor film 85 as indicated by arrows. Then, annealing processing (e.g., at 450° C. for one hour) is carried out in a nitrogen atmosphere to activate the impurity, thereby forming a source region 91 and a drain region 92 in the island-shaped semiconductor film 85 on both sides of a channel region 90. A position of such a channel region 90 is set in such a manner that a carrier moves along in a growth direction of each needle-like or elongate crystal. Then, as shown in FIG. 24E, an interlayer insulating film 89 that covers the entire product is formed, and a contact holes are is formed in this interlayer insulating film 89 and the gate insulating film 86, and then thereby forming a source electrode 93 and a drain electrode 94 are formed in the holes so that they are respectively connected with the source region 91 and the drain region 92.

At the above-explained steps, when the gate electrode 87 is formed in accordance with a position in a plane direction of each crystal having a large particle diameter of the polycrystal semiconductor film or the single-crystallized semiconductor film 84 generated at the steps depicted in FIGS. 24A and 24B, thereby forming the channel 90 below the gate electrode 87. With the above-explained steps, a polycrystal transistor or a thin film transistor (a TFT) ion the single-crystallized semiconductor can be formed. The thus manufactured polycrystal transistor or single-crystallized transistor can be applied to a drive circuit of a liquid crystal display (a display) or an EL (electroluminescence) display or an integrated circuit, e.g., a memory (an SRAM or a DRAM) or a CPU. The processing target in the present invention is not restricted to one on which a semiconductor device is formed, and the semiconductor device is not restricted to a TFT either.

In the above explanation, the present invention is applied to the crystallization apparatus and the crystallization method which illuminate a non-single-crystal semiconductor film with light having a predetermined light intensity distribution to generate a crystallized semiconductor film. However, the present invention is not restricted thereto, and it can be generally applied to a light irradiation apparatus which forms a predetermined light intensity distribution on a predetermined plane through an image forming optical system.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A light irradiation apparatus comprising:
a light modulation element which has a step line of a phase step having a phase difference substantially different from 180 degrees, and modulates a phase of incident light;
an illumination optical system which illuminates the light modulation element with illumination light inclined in a direction substantially perpendicular to the step line of the phase step; and
an image forming optical system which forms a light intensity distribution on a plane to be crystallized based on the light subjected to phase modulation by the light modulation element,
wherein the illumination optical system simultaneously illuminates the light modulation element with first illumination light which illuminates the light modulation element along a first direction extending from a phase advance side toward a phase retardation side of the phase step and second illumination light which illuminates the light modulation element along a second direction extending from the phase retardation side toward the phase advance side of the phase step, and has a light intensity setting mechanism which sets a light intensity of the first illumination light and a light intensity of the second illumination light to values substantially different from each other.

2. The apparatus according to claim 1, wherein the light intensity setting mechanism has a light intensity ratio varying unit which variably sets a ratio of the light intensity of the first illumination light and the light intensity of the second illumination light.

3. The apparatus according to claim 2, wherein the light intensity ratio varying unit has a polarizing prism which is arranged near the light modulation element and from which light exits in a direction which differs depending on a polarizing direction of incident light, and a polarization adjustment member which is provided on a beams source side away from the polarizing prism and adjusts the polarizing direction of the incident light entering the polarizing prism.

4. The apparatus according to claim 3, wherein the polarizing prism is a Wollaston prism.

5. The apparatus according to claim 3, wherein the polarization adjustment member has a retardation plate which is rotatable around an optical axis of the illumination optical system.

6. The apparatus according to claim 2, wherein the light intensity ratio varying unit has a light intensity modulation member which is provided at a position corresponding to an exit pupil of the illumination optical system or a position near the position and adjusts at least one of the light intensity of the first illumination light and the light intensity of the second illumination light.

7. The apparatus according to claim 6, wherein the light intensity modulation member has a first opening portion which allows the first illumination light to be transmitted therethrough, a second opening portion which allows the second illumination light to be transmitted therethrough, and a transmission factor modulation member which is arranged on a front side or a rear side of at least one of the first opening portion and the second opening portion.

8. The apparatus according to claim 6, wherein the light intensity modulation member has a first opening portion which allows the first illumination light to be transmitted therethrough and a second opening portion which allows the second illumination light to be transmitted therethrough, and a size of at least one of the first opening portion and the second opening portion is variably configured.

9. The apparatus according to claim 1, wherein the light modulation element has the phase step having a phase difference which is substantially larger than 0 degree and substantially smaller than 180 degrees, and
the light intensity setting mechanism sets the light intensity of the first illumination light to be substantially larger than the light intensity of the second illumination light.

10. The apparatus according to claim 1, wherein the light modulation element has the phase step having a phase difference which is substantially larger than 180 degrees and substantially smaller than 360 degrees, and
the light intensity setting mechanism sets the light intensity of the second illumination light to be substantially larger than the light intensity of the first illumination light.

11. The apparatus according to claim 1, wherein the light modulation element has a phase modulation pattern which is used to form a light intensity distribution whose intensity varies along a direction of the step line of the phase difference.

12. The apparatus according to claim 1, wherein the phase step is formed based on a difference in vectorial average value between phase modulation amounts in a point spread function range of the image forming optical system.

13. A crystallization apparatus comprising: the light irradiation apparatus according to any one of claims 1 to 12; and a stage which holds a non-single-crystal semiconductor film on said plane, wherein the crystallization apparatus irradiates the non-single-crystal semiconductor film held on said plane with light having the light intensity distribution to generate a crystallized semiconductor film.

14. A crystallization method which uses the light irradiation apparatus according to any one of claims 1 to 12 to irradiate a non-single-crystal semiconductor film held on said plane with light having the light intensity distribution, thereby generating a crystallized semiconductor film.

15. A device manufactured by using the crystallization apparatus according to claim 13.

16. A device manufactured by using the crystallization method according to claim 14.
